(19) United States
(12) Patent Application Publication
(10) Pub. No.: US 2026/0339880 A1
(43) Pub. Date: Oct. 29, 2026

(54) Low Power Bus Reset Scheme

(71) Applicant: Texas Instruments Incorporated, Dallas, TX (US)

(72) Inventors: Nikhil Goyal, BENGALURU (IN); Rejin K Kanjavalappil Raveendranath, BANGALORE (IN); Abhijit Anant Patki, Bengaluru (IN); Lokesh Kumar Botcha, BENGALURU (IN)

(21) Appl. No.: 19/656,580

(22) Filed: Apr. 23, 2026

(30) Foreign Application Priority Data
Apr. 25, 2025 (IN) 202541039843

(51) Int. Cl. G06F 13/42; G06F 1/26; H03K 19/0175

(52) U.S. Cl. CPC G06F 13/4282; G06F 1/266; H03K 19/017509

(57) ABSTRACT

A method is disclosed herein. The method includes detecting, by a reset circuit, a pulse signal on a signal bus, deactivating, by the reset circuit, a reset signal to an interface control circuit in response to detecting the pulse signal, and transitioning, by the interface control circuit, from a first power state to a second power state in response to the deactivation of the reset signal. The method further includes activating, by the interface control circuit, a loopback signal to the reset circuit based on the deactivation of the reset signal, after transitioning to the second power state and maintaining, by the reset circuit, the deactivation of the reset signal in response to the activation of the loopback signal.

### CROSS-REFERENCE TO RELATED APPLICATIONS

This application claims priority to India Provisional Patent Application No. 202541039843, filed Apr. 25, 2025, which is hereby incorporated by reference in its entirety.

### BACKGROUND

Systems that process audio data in modern electronic devices often include multiple audio-related components, such as microphones, audio codecs, speaker, and speaker amplifiers, that communicate with a host processor. Previous audio interfaces may use dedicated connections between the host processor and each audio component, which can increase device pin count, routing complexity, and power consumption. To address these challenges, serial communication interfaces have been developed that allow multiple audio peripherals to communicate with the host device over a shared bus. One example is the MIPI SoundWire® I3S (SWI3S™) protocol defined by the MIPI Alliance. Systems that implement the SWI3S™ protocol generally include a manager device (e.g., a host processor) coupled to multiple peripheral devices (e.g., various audio devices) through a signal bus that conveys clock and data signaling. The manager may control communication over the signal bus, including configuration of the peripheral devices and allocation of communication resources among the peripheral devices, while the peripheral devices transmit and receive audio data and control information over the signal bus.

### SUMMARY

A method is disclosed herein. The method includes detecting, by a reset circuit, a pulse signal on a signal bus, deactivating, by the reset circuit, a reset signal to an interface control circuit in response to detecting the pulse signal, and transitioning, by the interface control circuit, from a first power state to a second power state in response to the deactivation of the reset signal. The method further includes activating, by the interface control circuit, a loopback signal to the reset circuit based on the deactivation of the reset signal, after transitioning to the second power state and maintaining, by the reset circuit, the deactivation of the reset signal in response to the activation of the loopback signal.

Also disclosed herein is a device. The device includes a reset circuit coupled to a signal bus and an interface control circuit coupled to the reset circuit. The reset circuit is configurable to provide a pulse detected signal in response to a pulse signal on the signal bus, provide an enable power signal based on the pulse detected signal and a loopback signal, and provide a reset signal in response to the enable power signal. The interface control circuit is configurable to receive the reset signal from the reset circuit and provide the loopback signal to the reset circuit based on the reset signal.

Also disclosed herein is a system. The system includes a signal bus, a manager device coupled to the signal bus, and a peripheral device coupled to the signal bus. The manager device is configurable to transmit a signal on the signal bus. The peripheral device is configurable to detect the signal on the signal bus while the peripheral device is in a first state, power on the peripheral device in response to the signal, while in the first state, and monitor the signal bus for a cold start sequence to transition the peripheral device into a second state.

The foregoing features and elements may be combined in any combination, without exclusivity, unless expressly indicated herein otherwise. These features and elements as well as the operation of the disclosed examples will become more apparent in light of the following description and accompanying drawings.

### BRIEF DESCRIPTION OF THE DRAWINGS

Reference will now be made to the accompanying drawings, which are not necessarily drawn to scale. While the drawings illustrate various examples employing the principles described herein, the drawings do not limit the scope of the claims.

FIG. 1 illustrates a system for communication over a signal bus, in accordance with various examples.

FIGS. 2A, 2B, and 2C illustrate a peripheral device used in the system of FIG. 1 and the various examples associated therewith.

FIGS. 3A, 3B, 3C, 3D, and 3E illustrate timing diagrams of the peripheral of FIGS. 2A-2C and the various examples associated therewith.

FIG. 4 illustrates a flow chart for a method of a device transitioning states based on a signal, in accordance with various examples.

### DETAILED DESCRIPTION

The following detailed description is presented for purposes of illustration and not of limitation. Benefits, advantages, and/or solutions to problems may be described with reference to various examples. The detailed description makes use of the various examples and refers to the accompanying drawings which illustrate the various examples described herein. The drawings, descriptions, and examples are described in sufficient detail to practice the disclosure. It is understood that connecting lines shown in the various drawings are intended to represent example functional relationships and/or physical couplings between various elements, but that other relationships and/or couplings are possible while remaining within the scope of the present disclosure. It will further be appreciated that the various drawings may not be drawn to scale in order to simplify and clarify the detailed description herein. Furthermore, it is understood that the descriptions and examples contained herein may permit the practice other examples using logical, chemical, and/or mechanical changes without departing from the spirit and scope of this disclosure. For example, the steps recited in method and process descriptions may be executed in a different order, additional process steps may be added, and/or process steps may be removed while remaining within the scope of the present disclosure.

Any reference to singular items and/or examples includes plural items and/or examples and any reference to more than one item and/or example may include a singular item and/or example. Similarly, references to “a”, “an”, or “the” may include one or more of the referenced items, unless stated otherwise. Any reference to connected, coupled, fixed, attached, or the similar words and/or phrases may include partial, full, temporary, removable, permanent, or the other connection options. Any reference to contact, or similar phrase, may include minimal contact or reduced contact. All ranges used herein may include both the upper and lower values of the ranges, including ratio limits, that are disclosed herein. Stated values may include at least the variation that is expected within the field in which the present disclosure is practiced and as would be understood and accepted to include values that are within 10% of a stated value. Similarly, the use of “approximately”, “about”, “substantially” or other similar term represents an amount that is close to the stated value and that may still achieve the stated, or desired, result and/or perform the stated, or desired, function and may refer to an amount that is within 10% of the stated value.

The accompanying drawings, and detailed description of the drawings, include reference numerals that may be repeated across multiple examples. The repetition of reference numerals is intended for simplicity and clarity of description and is not intended to form or dictate a relationship between different examples described herein. The examples and descriptions provided herein are intended to be illustrative and not limiting beyond the scope of the claims.

The MIPI SoundWire® I3S (SWI3S™) specification defines a protocol of command and control signals between one or more managers and one or more peripherals. The command and control signals are transmitted and received over a signal bus (e.g., a serial signal bus) that couples the manager(s) to the various peripherals. Each peripheral uses various registers and internal states to track its connections and communications with the manager over the signal bus according to the SWI3S™ protocol. The peripherals support various Link-Active states (e.g., Syncing and Attached) and two Link-Inactive states (e.g., Sleeping and Cold_Standby). Generally, the Sleeping state is a lower power state used when the peripheral is not actively processing data. While in the Sleeping state, the peripheral may retain most register values and internal states, consuming less power than in one of the Link-Active states. Retaining the register values and internal states allows the peripheral start-up without re-initializing the register values and internal states.

Generally, the Cold_Standby, by contrast, is an even further lower power state (e.g., little to no power consumed) and may remove power from all or almost all circuitries, as defined by the SWI3S™ protocol specification. Removing power from the circuitry loses most, or all, register values and internal states. Therefore, the Cold_Standby state consumes less power than the Sleeping state and has a slower start-up time relative to the Sleeping state because the values of the registers and the internal states are re-initialized. However, in practice, it is difficult to achieve the goal of little to no power draw while in the Cold_Standby because the peripheral must respond to reset signaling sent by the manager on the signal bus while in the Cold_Standby state.

In general, while in the Cold_Standby state, the peripheral monitors the signal bus for a startup-sequence (e.g., a Bus Reset sequence or a Cold Start sequence) to trigger a transition from the Cold_Standby state to one of the Link-Active states. Various peripheral designs keep at least some circuitry powered-on while in the Cold_Standby state in order to monitor the signal bus for the startup-sequence. Accordingly, the power consumed in the Cold_Standby state tends to be closer to the power consumed in the Sleeping state. For example, an extra pin and signal (e.g., not on the signal bus) may be used to provide the peripheral an indication that the start-up sequence (e.g., the Cold Start sequence) is being transmitted on the signal bus. As described in further detail below, the peripheral may monitor the signal bus for the Cold Start sequence (e.g., including the Bus Reset sequence) to begin the transition from the Cold_Standby state to a Link-Active state.

Disclosed herein are systems and methods that enable the peripheral to monitor the signal bus in the Cold_Standby state while consuming little to no power. The systems and methods disclosed herein further still allow the peripheral to transition from the Cold_Standby state to a Link-Active state in response to signals on the signal bus. Using these systems and methods, the peripheral may remove almost all power (e.g., little to no power draw/consumption) from its circuitry while monitoring the signal bus for signaling to transition from the Cold_Standby state to a Link-Active state. In various examples, a pulse signal may be transmitted on the signal bus before transmitting the Cold Start sequence. In some examples, the peripheral may include circuitry configurable to power up the peripheral in response to the pulse signal to enable the peripheral to monitor the signal bus for the Cold Start sequence while staying in the Cold_Standby state. In some examples, the peripheral may power-down the circuitry in response to not detecting a subsequent Cold Start sequence. In other examples, the peripheral may remain powered on in response to detecting the Cold Start sequence and continue processing control signals that cause the peripheral to transition to a Link-Active state.

In various examples, the peripheral may include a reset loopback circuit that is configurable to detect the pulse signal (e.g., single pulse) on the signal bus and wake-up (e.g., power-on) the peripheral to monitor for additional signals. In some examples, the reset loopback circuit may include a power-on reset (POR) circuit, a pulse detection circuit, and an interface control circuit (including a bus inactivity detection circuit), among others. In such examples, the POR circuit may provide a reset signal to the interface control circuit, and the interface control circuit may provide a loopback signal to the POR circuit. For example, the reset signal provided by the POR circuit may, when active, hold the interface control circuit in reset.

In various examples, in response to detecting the pulse signal, the pulse detection circuit may provide a power enable signal to the POR circuit and the POR circuit may in turn deactivate the reset signal to the interface control circuit. The interface control circuit may power on and activate a loopback signal to the POR circuit, which in various examples, maintains the power enable signal to the POR circuit active to keep the interface control circuit out of reset. In some examples, the bus inactivity detection circuit may monitor the signal bus for activity and disable the loopback signal in response to not detecting activity on the signal bus for a predetermined time period. Deactivating the loopback signal may result in the POR circuit activating the reset signal and holding the interface control circuit in reset.

Accordingly, the reset loopback circuit, in various examples, and as described in detail below, allows the peripheral to enter a very low-power state (e.g., little to no power consumed) while in the Cold_Standby state and still wake-up (e.g., power-on) in response to the pulse signal on the signal bus. Moreover, the reset loopback circuit does not use additional pins, reducing the overall pin count of the peripheral as compared to various previous systems. Additional details are described in detail below. While examples consistent with the present disclosure may provide these and other beneficial effects, no particular result is a requirement unless explicitly recited in a particular.

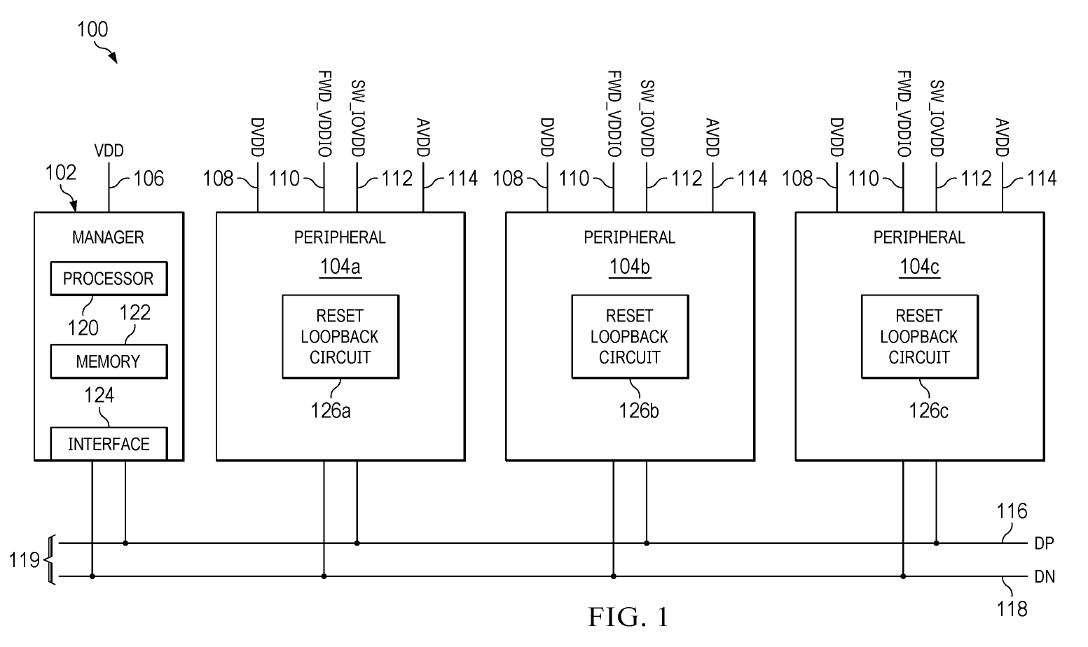

Referring to FIG. 1, a system 100 that implements a signal bus (e.g., a serial signal bus) in accordance with the MIPI SoundWire® I3S (SWI3S™) protocol specification is illustrated, according to various aspects of the present disclosure. System 100 may be used in smartphones, tablets, computers, wearables, headsets, automobiles, smart home devices, and internet of things devices, among others. System 100 includes a manager 102, a first peripheral 104a, a second peripheral 104b, and a third peripheral 104c (collectively referred to herein as peripherals 104). Manager 102 and peripherals 104 communicate with each other using a signal bus 119 (e.g., a serial signal bus).

Signal bus 119 may include a plurality of signal lines. In various examples, the plurality of signal lines may include a data positive signal line (DP) 116 and a data negative signal line (DN) 118 that are configurable to convey clock signaling and data signaling between the manager 102 and each of the peripherals 104. Other configurations of signal bus 119 are possible and within the scope of the present disclosure.

Manager 102 is coupled to VDD 106 (e.g., a power source, a drain supply voltage, or a positive voltage) and to signal bus 119, including both DP 116 and DN 118. Manager 102 includes a processor 120, a memory 122, and interface circuitry 124. Manager 102 is configurable to control peripherals 104, including controlling the operation of signal bus 119, such as generating clock signaling and transmitting control and data signals to peripherals 104 on signal bus 119. Interface circuitry 124 may control communication between manager 102 and signal bus 119.

In some examples, manager 102 may send one or more control signals (e.g., a signal sequence) to peripherals 104 on signal bus 119 that cause peripherals 104 to enter one of two Link-Inactive states, e.g., the Sleeping state or the Cold_Standby state. In other examples, manager 102 may send one or more control signals to peripherals 104 on signal bus 119 that cause peripherals 104 to enter any one of the various Link-Active states (e.g., Syncing, Attached) defined and described in the SWI3S™ protocol specification. In various examples, manager 102 may additionally be coupled to another controller (or microcontroller) (not shown) and may be configurable to pass data from the other controller to one or more of peripherals 104.

Processor 120 may comprise one or more processors configurable to implement various logical operations in response to the execution of instructions, for example, instructions stored on a non-transitory, tangible, computer-readable medium. The one or more processors can be a processing chip, a general purpose processor, a microprocessor, a microcontroller, a digital signal processor (DSP), a system-on-chip (SoC), an application specific integrated circuit (ASIC), a field programmable gate array (FPGA) or other programmable logic device, discrete or transistor logic, discrete hardware components, or any combination thereof.

Memory 122 may comprise memory to store data, executable instructions, system program instructions, and/or controller instructions to implement the control logic of processor 120. Memory 122 may include one or more of random access memory (RAM), flash memory, electrically erasable programmable read-only memory (EEPROM), and/or other transitory and non-transitory memory devices.

Interface circuitry 124 may be coupled to signal bus 119 (e.g., DP 116 and DN 118). In some examples, interface circuitry 124 may be configurable to manage communications for manager 102 on signal bus 119. For example, interface circuitry 124 may provide signals to processor 120 from signal bus 119 and provide signals from processor 120 to signal bus 119.

Peripherals 104 are coupled to various power sources (e.g., power supplies) and to signal bus 119 (e.g., DP 116 and DN 118). In various examples, the power supplies may include a drain supply voltage (VDD) 108 (e.g., positive supply), an input/output supply voltage (FWD_VDDIO) 110, a SWI3S I/O supply voltage (SW_IOVDD) 112, and an analog VDD (AVDD) 114. Peripherals 104 may communicate control information and audio data with the manager over signal bus 119. As described herein, the systems and methods may be implemented using peripherals having six pins. For example, each peripheral 104 (e.g., first peripheral 104a, second peripheral 104b, and third peripheral 104c) may include four power pins and two data pins. For example, each of the four power pins may be coupled to one of DVDD 108, FWD_VDDIO 110, SW_IOVDD 112, or AVDD 114 and each data pin may be connected to either DP 116 or DN 118. In other examples, one or more of the peripherals 104 may include additional pins and/or other connections to manager 102 and/or other components of system 100.

Each peripheral 104 (e.g., first peripheral 104a, second peripheral 104b, and third peripheral 104c) includes a reset loopback circuit 126. For example, first peripheral 104aincludes a reset loopback circuit 126a, second peripheral 104b includes a reset loopback circuit 126b, and third peripheral 104c includes a reset loopback circuit 126c. Each reset loopback circuit 126 enables the corresponding peripheral 104 to transition from the Cold_Standby to a Link-Active state in response to a pulse signal (e.g., a single pulse signal) on signal bus 119. The reset loopback circuit 126 enables each peripheral 104 to draw little to no power while in the Cold_Standby state and to transition from the Cold_Standby state without using an additional pin or a signal external to signal bus 119, as in some previous systems. As described above, peripherals 104 may have two Link-Inactive states (Sleeping and Cold_Standby) and various Link-Active states (e.g., Syncing and Attached). In various examples, peripherals 104 may transition to or from either of the Link-Inactive states in response to one or more signals and/or signal sequences on signal bus 119.

Peripherals 104 may include audio-related components, such as microphones, amplifiers, codecs, sensors, or other devices configurable to exchange data with manager 102 over signal bus 119. Each peripheral 104 may include interface circuitry configurable to receive signaling from manager 102 and transmit signaling to manager 102 using the signal bus 119. Each peripheral 104 may further include circuitry to respond to command or control information transmitted by manager 102 on signal bus 119.

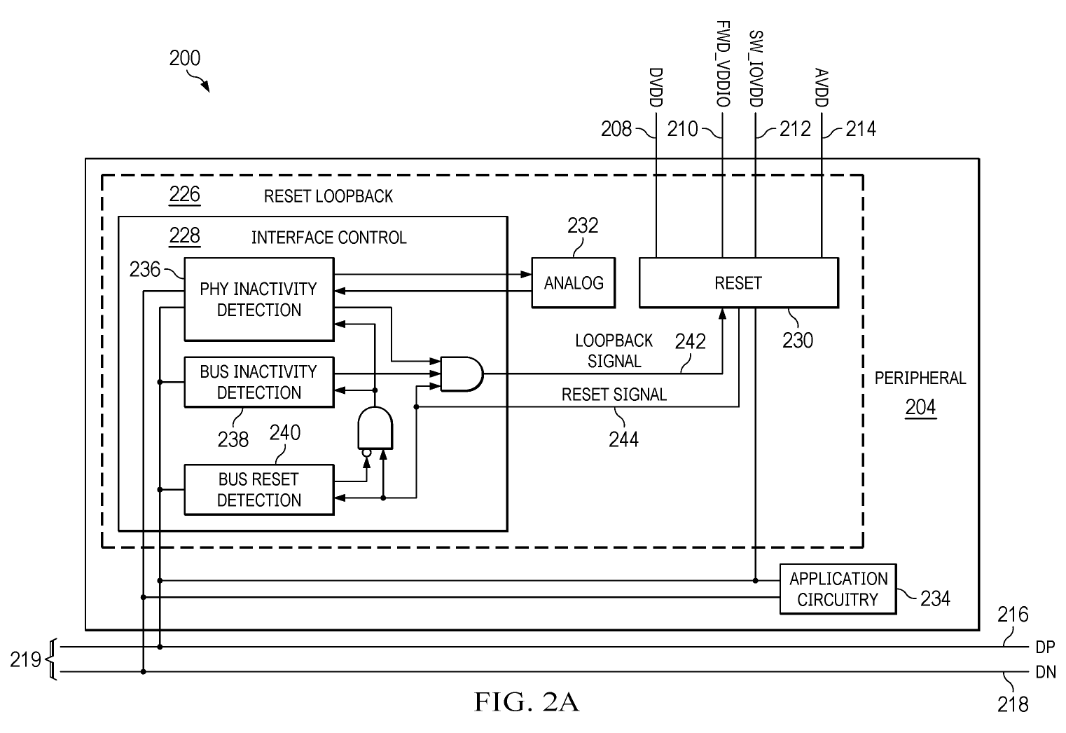

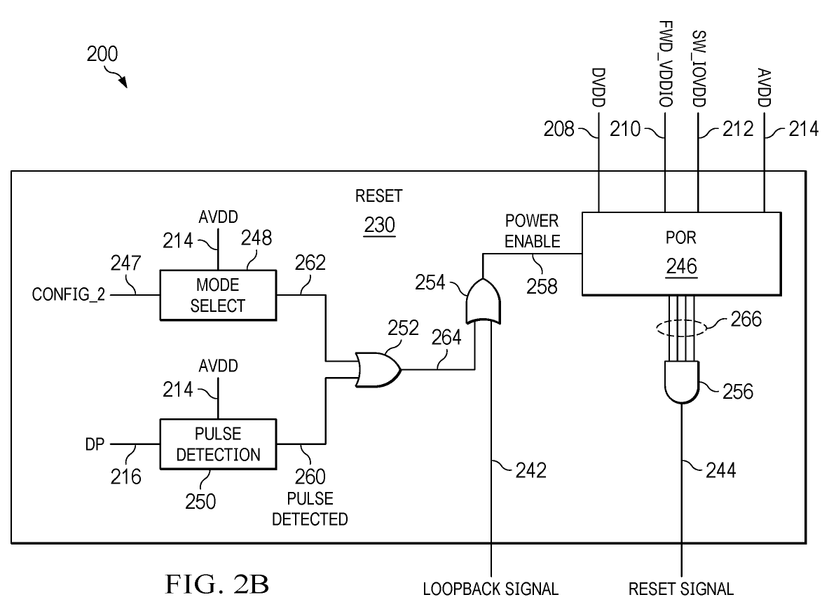

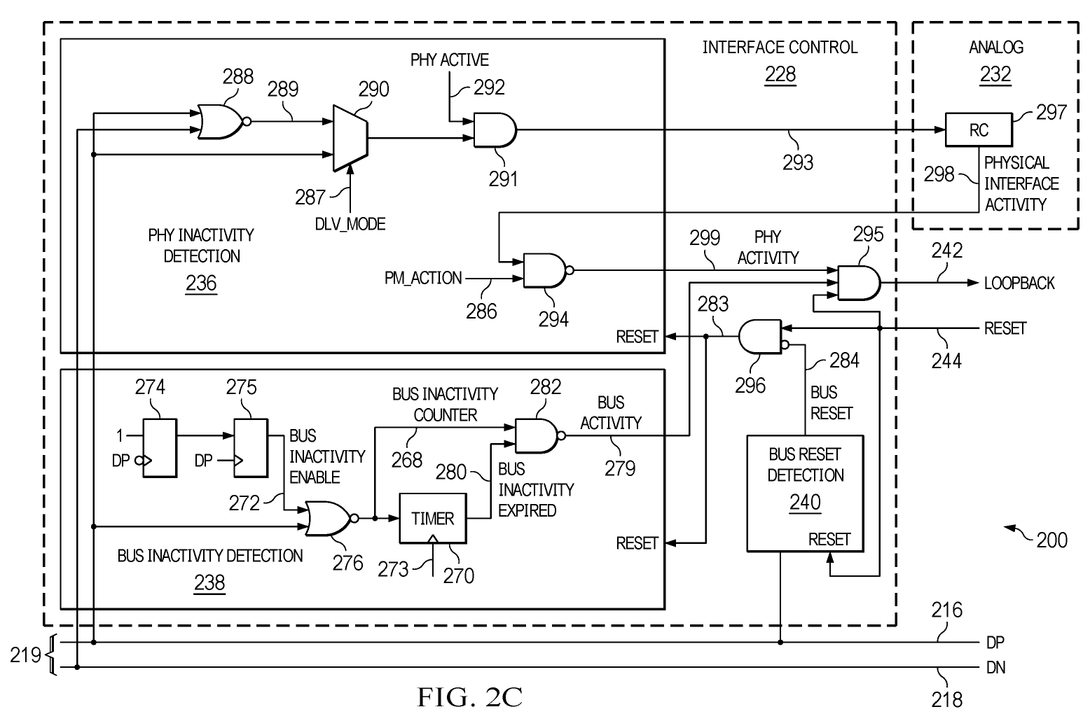

Referring now to FIGS. 2A-2C, a system 200 that implements a signal bus (e.g., a serial signal bus) in accordance with the MIPI SoundWire® I3S (SWI3S™) protocol specification is illustrated, according to various aspects of the present disclosure. System 200 includes similar components to system 100 described above in FIG. 1, including a peripheral 204, a signal bus 219 (including DP 216 and DN 218), and a reset loopback circuit 226. In that regard, FIG. 2A provides a high level block diagram of peripheral 204 including reset loopback circuit 226 and application circuitry 234. Reset loopback circuit 226 further includes an interface control circuit 228, a reset circuit 230, an analog circuit 232. FIG. 2B is a detailed block diagram of reset circuit 230. FIG. 2C is a detailed block diagram of interface control circuit 228 and analog circuit 232. The components of peripheral 204 shown in FIG. 2A are examples of an implementation of the systems and methods described herein. Accordingly, circuitry may be added or removed from system 200 while remaining within the scope of the present disclosure.

Reset loopback circuit 226 may be implemented using multiple different circuits, and as such, may be referred to as a functional grouping of circuits. In that regard, reset loopback circuit 226 includes interface control circuit 228, reset circuit 230, and analog circuit 232. In various examples, interface control circuit 228, reset circuit 230, and analog circuit 232 may be implemented on a single substrate (e.g., a single die or a single printed circuit board (PCB)) or on multiple substrates. Reset loopback circuit 226 may facilitate power management of peripheral 204 while peripheral 204 is in one of the various states supported by peripheral 204.

In that regard, reset loopback circuit 226 enables peripheral 204 to draw little to no power in the Cold_Standby state while still being able to respond to a wake-up signal (e.g., the Cold Start sequence) on signal bus 219. For example, reset loopback circuit 226 may detect a pulse signal on signal bus 219, while drawing little to no power, and power up peripheral 204 in response to the pulse signal. As described above, previous solutions for managing the Cold_Standby state in a peripheral include using a dedicated signal line (e.g., a dedicated input pin, not signal bus 219) to provide a wake-up signal. The dedicated signal line may be constantly monitored such that some of the circuitry (e.g., a power-on reset circuit) must remain powered on (e.g., increasing power use) while in the Cold_Standby state so that the peripheral can respond to the wake-up signal. As described herein, peripheral 204 may respond to a wake-up signal on signal bus 219 (e.g., without using a dedicated pin) and while drawing little to no power in the Cold_Standby state.

In that regard, reset circuit 230 may be configurable to hold interface control circuit 228 in reset, prohibiting operation of interface control circuit 228, while peripheral 204 is in the Cold_Standby state. For example, reset circuit 230 may be configurable to activate a reset signal 244 that holds interface control circuit 228 in reset (e.g., powered down or drawing no power). Reset circuit 230 may further be configurable to monitor signal bus 219 (e.g., DP 216) for a pulse signal (e.g., a startup pulse or a single pulse) and deactivate reset signal 244 in response to detecting the pulse signal. For example, reset circuit 230 may detect the pulse signal on signal bus 219 and deactivate reset signal 244 in response to detecting the pulse signal.

In response to reset circuit 230 deactivating reset signal 244, interface control circuit 228 may power on and may activate loopback signal 242 to reset circuit 230. For example, interface control circuit 228 may transition from a first power state (e.g., a power down state) to a second power state (e.g., a power on state) in response to the deactivation of reset signal 244 while in the Cold_Standby state. Loopback signal 242 provides a feedback signal to reset circuit 230 to keep reset signal 244 deactivated (e.g., reset circuit 230 powered on or awake) after the pulse signal ends and while interface control circuit 228 monitors signal bus 219 for additional signaling. For example, reset circuit 230 maintains the deactivation of reset signal 244 in response to the activation of loopback signal 242. In various examples, interface control circuit 228 includes a physical layer (PHY) inactivity detection circuit 236 that monitors signal bus 219 for PHY activity and a bus inactivity detection circuit 238 that monitors signal bus 219 for any bus activity. In some examples, PHY inactivity detection circuit 236 monitors signal bus 219 for PHY activity during operation (e.g., in a Link-Active state) of peripheral 204. In some examples, bus inactivity detection circuit 238 monitors signal bus 219 for bus activity during startup of peripheral 204 and/or after a bus reset (e.g., in a Link-Inactive state). The loopback signal 242 may be activated by interface control circuit 228 in response to reset signal 244 and the outputs of PHY inactivity detection circuit 236 and bus inactivity detection circuit 238, details of which are described in further detail below with respect to FIG. 2C.

Bus reset detection circuit 240, in various examples, monitors signal bus 219 for a Bus Reset sequence. For example, bus reset detection circuit 240 may monitor signal bus 219 for the Bus Reset sequence and reset interface control circuit 228 in response to detecting the Bus Reset sequence. Operation of bus reset detection circuit 240 is inhibited (e.g., held in reset) by reset signal 244, similar to PHY inactivity detection circuit 236 and bus inactivity detection circuit 238. In various examples, bus reset detection circuit 240 may monitor signal bus 219 for the Bus Reset sequence when powered on (e.g., not held in reset) regardless of the state of peripheral 204 (e.g., Link-Active or Link-Inactive). Responsive to reset signal 244 being deactivated, bus reset detection circuit 240 begins to monitor signal bus 219 for the Bus Reset sequence and provides an output that, when combined with reset signal 244, holds PHY inactivity detection circuit 236 and bus inactivity detection circuit 238 in reset. In other words, PHY inactivity detection circuit 236 and bus inactivity detection circuit 238 may be held in reset by either reset signal 244 or a signal from bus reset detection circuit 240 indicating that the Bus Reset sequence was detected on signal bus 219.

Application circuitry 234 performs the primary task of peripheral 204. In that regard, application circuitry 234 may be configurable to perform one or more device-specific operations, such as audio conversion, signal processing, amplification, and/or sensing, among others. For example, application circuitry 234 may include analog-to-digital converters (ADCs), digital-to-analog converters (DACs), audio codecs, amplifiers, filters, transistors, resistors, capacitors, and/or inductors, among others. In various examples, application circuitry 234 may be held in reset by interface control circuit 228 while peripheral 204 is in the Link-Inactive state. In some examples, interface control circuit 228 may hold application circuitry 234 in rest until transitioning to a Link-Active state. In other examples, interface control circuit 228 may hold application circuitry 234 in reset until after receiving the Bus Reset sequence or at any other time depending on the design of peripheral 204.

Referring to FIG. 2B, a detailed block diagram of reset circuit 230 is shown. Reset circuit 230 includes a power-on reset (POR) circuit 246, a mode select circuit 248, a pulse detection circuit 250, and logic circuits 252, 254, and 256. In some examples, reset circuit 230 may include additional circuitry.

POR circuit 246 is coupled to various power sources (e.g., power supplies, DVDD 208, FWD_VDDIO 210, SW_IOVDD 212, and AVDD 214) and is configurable to receive a power enable signal 258 (described in further detail below) and provide reset signal 244 (in combination with logic circuit 256) to the other circuits in peripheral 204 (e.g., interface control circuit 228). Generally, POR circuit 246 prevents unintended operation of peripheral 204 during power on. For example, when power is initially applied to peripheral 204 the voltages and/or currents of DVDD 208, FWD_VDDIO 210, SW_IOVDD 212, and AVDD 214 are not stable which may cause unintended operation of peripheral 204 if the various circuits of peripheral 204 are allowed to operate immediately after power is applied. Therefore, POR circuit 246 monitors the power supplies and activates reset signal 244 to hold the other components in reset until the power supplies stabilize. POR circuit 246 includes circuitry configurable to monitor the voltage and current of DVDD 208, FWD_VDDIO 210, SW_IOVDD 212, and AVDD 214 and provide one or more power valid signals 266 in response to the voltage and/or current of each power supply reaching a threshold stability (e.g., variation below a threshold). In various examples, reset signal 244 may be an active low signal so that the various circuits and components of peripheral 204 are held in reset when no power is applied to reset signal 244 (e.g., by POR circuit 246).

As each power supply stabilizes, POR circuit 246 outputs the power valid signals 266 to logic circuit 256 which outputs reset signal 244 based on the power valid signals 266. In some examples, logic circuit 256 may generate the reset signal 244 corresponding to a logical AND of the power valid signals 266. In other examples, logic circuit 256 may generate the reset signal 244 corresponding to a logical NAND of the power valid signals 266. As described herein, reset signal 244 may be an active low signal and the power valid signals 266 may be active high signals, so that reset signal 244 is deactivated (e.g., high level) in response to the power valid signals 266 being activated (e.g., high level).

Mode select circuit 248 may be configurable to identify a mode of operation. In various examples, the mode of operation may be based on the value of a CONFIG_2 register 247 of peripheral 204. The value of the CONFIG_2 register 247 indicates whether peripheral 204 is operating using the SWI3S™ protocol or another protocol (e.g., the Inter-Integrated Circuit (IC) Sound (I2S) protocol). Mode select circuit 248 outputs mode select signal 262 based on the value of the CONFIG_2 register 247. In some examples, a logic low value of mode select signal 262 may indicate that peripheral 204 is operating using the SWI3S™ protocol and a logic high value of mode select signal 262 may indicate that peripheral 204 is operating using a different protocol (e.g., the Inter-Integrated Circuit (IC) Sound (I2S) protocol). In other examples, the output of mode select circuit 248 may be inverted by another component (e.g., an inverted buffer) so that the logic values of mode select signal 262 are opposite of those described above. Accordingly, mode select circuit 248 may allow peripheral 204 to be compatible with other protocols (e.g., backwards compatible). While mode select circuit 248 is included herein for completeness and to demonstrate backwards (or other) compatibility, for simplicity and clarity, no further discussion of mode select circuit 248 is provided. Accordingly, mode select circuit 248 will be considered as being set to the SWI3S™ mode (e.g., logic low value) for the remainder of the discussion.

Pulse detection circuit 250 is coupled to the signal bus (e.g., DP 216, signal bus 219 of FIG. 2A) and may be configurable to monitor DP 216 for a pulse signal (e.g., a single pulse) to wake up (e.g., power on) peripheral 204. In that regard, pulse detection circuit 250 may be configurable to output a pulse detected signal 260 in response to detecting the pulse signal on DP 216. In various examples, the pulse signal on DP 216 has a first duration, and the pulse detected signal 260 generated by pulse detection circuit 250 has a second duration that is greater than the first duration. In various examples, the second duration being greater than the first duration may enable the peripheral 204 to recognize shorter signals on DP 216 (e.g., the pulse signal). For example, the second duration may be greater than the first duration so that pulse detection circuit 250 activates the pulse detected signal 260 for longer than the first duration of the signal pulse. In various examples, the first duration may be about 1 µs to about 5 µs and the second duration may be about 20 µs to about 60 µs. As shown in FIG. 2B, pulse detected signal 260 may be an active high signal. For example, pulse detection circuit 250 may assert pulse detected signal 260 high (e.g., active) in response to DP 216 being high (e.g., representing the pulse signal) and assert pulse detected signal 260 low (e.g., inactive) in response to DP 216 being low.

In other examples, pulse detection circuit 250 may output an active low signal that is later inverted or may be inverted before being output by pulse detection circuit 250. For example, pulse detection circuit 250 may be or include a resistor, a capacitor, and a transistor to form a resistor-capacitor (RC) circuit that is activated by the transistor. For example, DP 216 may be connected to the gate of the transistor to control the output of pulse detection circuit 250. In such examples, the capacitor may charge to the high level in response to DP 216 being low, so that pulse detection circuit 250 outputs a high level. The capacitor may rapidly discharge in response to DP 216 being high (e.g., activating the transistor) so that pulse detection circuit 250 generates a low signal. The capacitor may slowly charge in response to DP 216 being low, resulting in pulse detection circuit 250 outputting the low level for the second duration while the capacitor charges. Accordingly, the second duration may be based on the selected values for the resistor and capacitor of pulse detection circuit 250. For simplicity and ease of understanding, pulse detected signal 260 is described herein as being active high.

Logic circuit 252 receives pulse detected signal 260 and mode select signal 262 as inputs and outputs an interlogic signal 264 based on the input signals. In various examples, logic circuit 252 may generate interlogic signal 264 corresponding to a logical OR of the pulse detected signal 260 and mode select signal 262 signals. In other examples, logic circuit 252 may generate interlogic signal 264 corresponding to a logical NOR of the pulse detected signal 260 and mode select signal 262. In either implementation, logic circuit 252 may keep interlogic signal 264 active in response to the CONFIG_2 register 247 being set to a mode other than the SWI3S™ protocol mode. However, as described above, the CONFIG_2 register 247 (and mode select circuit 248) are set to the SWI3S™ protocol mode (e.g., logic low value), therefore the logic circuit 252 generates interlogic signal 264 in response to the pulse detected signal 260.

Logic circuit 254 receives interlogic signal 264 and loopback signal 242 as inputs and outputs power enable signal 258 based on the input signals. In various examples, logic circuit 254 may generate power enable signal 258 corresponding to a logical OR of the interlogic signal 264 and loopback signal 242. In other examples, logic circuit 254 may generate power enable signal 258 corresponding to a logical NOR of the interlogic signal 264 and loopback signal 242. In either implementation, logic circuit 254 activates power enable signal 258 in response to either interlogic signal 264 or loopback signal 242 being active.

Accordingly, during operation, peripheral 204 may be in the Cold_Standby state with reset signal 244 activated and both the power enable signal 258 and the loopback signal 242 may be deactivated. While in the Cold_Standby state, pulse detection circuit 250 may detect a pulse signal on signal bus 219 and activate pulse detected signal 260 for the second duration. During the second duration, logic circuit 254 activates power enable signal 258 in response to pulse detected signal 260 being active and then POR circuit 246 powers on in response to power enable signal 258 being active. Powering on POR circuit 246 causes reset signal 244 to be deactivated by logic circuit 256 and interface control circuit 228 may exit reset in response to reset signal 244 being deactivated. As described above, interface control circuit 228 activates and sends loopback signal 242 to reset circuit 230 (e.g., logic circuit 254). Logic circuit 254 may then output power enable signal 258 in response to both the pulse detected signal 260 and the loopback signal 242 being activated for the remainder of the second duration. After the second duration, pulse detected signal 260 is deactivated by pulse detection circuit 250 but power enable signal 258 remains activate because loopback signal 242 is activate, thus preventing POR circuit 246 from reactivating reset signal 244. Descriptions of loopback signal 242 being activated and deactivated are described below in FIG. 2C.

The loopback (e.g., loopback signal 242) described herein keeps peripheral 204 awake (e.g., powered on) for longer than the first and second durations based on the pulse signal on signal bus 219 (FIG. 2A) having the first duration. This extended duration enables peripheral 204 to monitor signal bus 219 for additional signal sequences without using an additional signal line (e.g., external to signal bus 219). Moreover, peripheral 204 may draw little to no power while monitoring signal bus 219 for the pulse signal because pulse detection circuit 250 may be implemented using an RC circuit having minimal power draw. Therefore, peripheral 204 may be able to draw little to no power while in the Cold_Standby state and pulse detection circuit 250 may be able to initiate the wake-up process to monitor signal bus 219 for signaling from a manager (e.g., manager 102).

Referring to FIG. 2C, a detailed block diagram of interface control circuit 228 and analog circuit 232 are shown. Interface control circuit 228 includes PHY inactivity detection circuit 236, bus inactivity detection circuit 238, bus reset detection circuit 240, and logic circuits 295 and 296. Analog circuit 232 includes a timer circuit 297. As described in more detail below, bus inactivity detection circuit 238 activates (e.g., asserts to logic high) a bus activity signal 279 in response to activity on DP 216 and deactivates (e.g., asserts to logic low) bus activity signal 279 in response to there being no activity on DP 216 for a predefined duration. Additionally, PHY inactivity detection circuit 236 activates (e.g., asserts to logic high) a PHY activity signal 299 in response to PHY activity on signal bus 219 and deactivates (e.g., asserts to logic low) PHY activity signal 299 in response to there being no PHY activity on signal bus 219 for a predefined duration.

Bus inactivity detection circuit 238 monitors signal bus 219 for signals on DP 216 of signal bus 219 (e.g., command and control signals). Bus inactivity detection circuit 238 deactivates a bus activity signal 279 (e.g., assert to logic low) in response to there being no activity on DP 216 for a third duration that is greater than the second duration. In various examples, the third duration may be greater than the length of the Bus Reset sequence. In various examples, the third duration may be about 200 µs to about 300 µs.

Bus inactivity detection circuit 238 includes a timer circuit 270, a first latch 274, a second latch 275, and logic circuits 276 and 282. First and second latches 274, 275 and logic circuit 276 receive DP 216 as an input signal. Logic circuit 276 further receives the output of second latch 275 as an input signal and outputs bus inactivity counter signal 268. Timer circuit 270 receives bus inactivity counter signal 268 and a clock signal 273 as inputs and outputs a bus inactivity expired signal 280. Logic circuit 282 receives bus inactivity counter signal 268 and bus inactivity expired signal 280 as inputs and outputs a bus activity signal 279. Bus activity signal 279 may be used by interface control circuit 228 (e.g., by logic circuit 295) in generating loopback signal 242.

First and second latches 274, 275 are coupled in series. First latch 274 may have a data input coupled to a logic high value (e.g., a constant value) and may be configurable to be responsive to a first transition of DP 216 (e.g., a falling edge). Second latch 275 may have a data input coupled to an output of first latch 274 and may be configurable to be responsive to a second transition of DP 216 (e.g., a rising edge). During operation, when DP 216 transitions from a first value to a second value (e.g., from a logic low value to a logic high value), second latch 275 may sample the output of first latch 274 and provide a corresponding output signal, such as the bus inactivity enable signal 272. When DP 216 subsequently transitions from the second value to the first value (e.g., from the logic high value to the logic low value), first latch 274 may capture the logic high value at its data input and update the signal provided to second latch 275. As a result, the output of second latch 275 may transition to a logic low value in response to the falling edge of the DP 216 signal (e.g., a pulse signal). In various examples, bus inactivity detection circuit 238 may be implemented using zero latches, one latch, or more than two latches while remaining within the scope of the present disclosure.

In some examples, logic circuit 276 may generate the bus inactivity counter signal 268 corresponding to a logical NOR of the DP 216 signal and the bus inactivity enable signal 272. In other examples, logic circuit 276 may generate bus inactivity counter signal 268 corresponding to a logical OR of the DP 216 signal ang the bus inactivity enable signal 272 (as shown). In either implementation, logic circuit 276 deactivates bus inactivity counter signal 268 when either DP 216 is high or bus inactivity enable signal 272 is high.

Timer circuit 270 may be configurable to start a timer having the third duration in response to activity on signal bus 219. Timer circuit 270 activates bus inactivity expired signal 280 (e.g., logic high value) in response to the timer expiring, which occurs at the end of the third duration. Timer circuit 270 may be reset (e.g., the timer starts over) in response to bus inactivity counter signal 268 being activated.

In some examples, logic circuit 282 may generate bus activity signal 279 corresponding to a logical NAND of the bus inactivity counter signal 268 and bus inactivity expired signal 280. In other examples, logic circuit 282 may generate bus activity signal 279 corresponding to a logical AND of the bus inactivity counter signal 268 and bus inactivity expired signal 280. In either implementation, logic circuit 282 may deactivate bus activity signal 279 when both bus inactivity counter signal 268 and bus inactivity expired signal 280 are activated. Accordingly, bus inactivity detection circuit 238 monitors signal bus 219 for command and control signals and activates bus activity signal 279 in response to one or more command and control signals occurring on signal bus 219 during the third duration. As described above, bus inactivity detection circuit 238 may monitor signal bus 219 for activity while in a Link-Inactive state (e.g., Cold_Standby).

PHY inactivity detection circuit 236 monitors signal bus 219 (FIG. 2A) for PHY signaling (e.g., physical interface signaling). In various examples, PHY signaling may be on a single line (e.g., DP 216 or DN 218) or on both lines (e.g., DP 216 and DN 218). PHY inactivity detection circuit 236 includes logic circuits 288, 291, and 294 and a multiplexer 290. Logic circuit 288 receives DP 216 and DN 218 as inputs and provides an interlogic signal 289 as output. In some examples, logic circuit 288 may be configurable to generate the interlogic signal 289 corresponding to a logical OR of DP 216 and DN 218. In other examples, logic circuit 288 may be configurable to generate interlogic signal 289 corresponding to a logical NOR of DP 216 and DN 218. In either implementation, interlogic signal 289 may be activated if either DP 216 or DN 218 is active.

Multiplexer 290 receives interlogic signal 289 and DP 216 as inputs and a DLV_mode signal 287 as a control input. Accordingly, multiplexer 290 outputs either interlogic signal 289 or DP 216 based on the value of DLV_mode signal 287. DLV_mode signal 287 indicates the PHY mode that peripheral 204 is operating in (e.g., differential low voltage (DLV) mode or forwarded-bit-clock single-ended (FBCSE) mode). If peripheral 204 is operating in DLV mode, multiplexer 290 outputs the value of DP 216. If peripheral 204 is operating in FBCSE mode, multiplexer 290 outputs interlogic signal 289.

Logic circuit 291 receives the output of multiplexer 290 and a PHY active signal 292 as inputs and outputs a PHY interface signal 293. In some examples, logic circuit 291 may be configurable to generate the PHY interface signal 293 corresponding to a logical AND of the output of multiplexer 290 and PHY active signal 292. In other examples, logic circuit 291 may be configurable to generate the PHY interface signal 293 corresponding to a logical NAND of the output of multiplexer 290 and PHY active signal 292. In either implementation, PHY interface signal 293 is activated when the output of multiplexer 290 and PHY active signal 292 are active. In various examples, PHY active signal 292 may be used to indicate a transition in the PHY state to help with transitions during power down of system 200. For example, PHY active signal 292 may show a transition from Audio PHY to low-capacitance (LC) PHY or to power off. PHY inactivity detection circuit 236 provides PHY interface signal 293 to timer circuit 297 of analog circuit 232.

Timer circuit 297 of analog circuit 232 is configurable to receive PHY interface signal 293 and output the value of PHY interface signal 293 as a physical interface activity signal 298 for a fourth time duration. In various examples, the fourth time duration may be about 400 µs to about 600 µs. In various examples, timer circuit 297 may be an RC circuit. The fourth time duration may be based on the selected values of the resistor(s) and/or capacitor(s) of timer circuit 297. Timer circuit 297 outputs physical interface activity signal 298 to PHY inactivity detection circuit 236, and in some examples, to logic circuit 294. In various examples, analog circuit 232 may include additional circuitry.

Logic circuit 294 of PHY inactivity detection circuit 236 receives PHY interface signal 293 and a PM_ACTION signal 286 as inputs and outputs a PHY activity signal 299. In some examples, logic circuit 294 may generate the PHY activity signal 299 corresponding to a logical AND of the PM_ACTION signal 286 and the PHY interface signal 293. In other examples, logic circuit 294 may generate the PHY activity signal 299 corresponding to a logical NAND of the PM_ACTION signal 286 and the PHY interface signal 293. In either implementation, PHY activity signal 299 is activated when both physical interface activity signal 298 and PM_ACTION signal 286 are active. PM_ACTION signal 286 provides the value stored in a PM_ACTION register. The value of PM_ACTION may be provided by the manager (e.g., manager 102) and may indicate a state to transition to (e.g., Enter_Cold_Standby, Enter_Sleeping, Stay_Attached, etc.) in response to a predefined condition (e.g., change to PM_ACTION register, PHY-specific condition, etc.).

Logic circuit 295 of interface control circuit 228 receives PHY activity signal 299, reset signal 244, and bus activity signal 279 as inputs and outputs loopback signal 242. In some examples, logic circuit 295 may generate the loopback signal 242 corresponding to a logical AND of the PHY activity signal 299, reset signal 244, and bus activity signal 279. In some examples, logic circuit 295 may generate the loopback signal 242 corresponding to a logical NAND of the PHY activity signal 299, reset signal 244, and bus activity signal 279. In either implementation, loopback signal 242 is activated (e.g., logic high value) when PHY activity signal 299 and bus activity signal 279 are active and reset signal 244 is inactive (e.g., all logic high values). Accordingly, loopback signal 242 is activated (e.g., logic high value) in response to PHY inactivity detection circuit 236 detecting PHY activity (e.g., on signal bus 219), bus inactivity detection circuit 238 detecting bus activity (e.g., on signal bus 219), and both reset signal 244 and bus reset signal being inactive (e.g., reset signal 283 is inactive (e.g., logic high value). Moreover, loopback signal 242 is inactive (e.g., logic low value) if PHY inactivity detection circuit 236 does not detect PHY activity for the fourth duration, bus inactivity detection circuit 238 does not detect bus activity for the third duration, or either of reset signal 244 or bus reset signal 284 is active. As described above, PHY inactivity detection circuit 236 may monitor signal bus 219 for activity while in a Link-Active state (e.g., during operation).

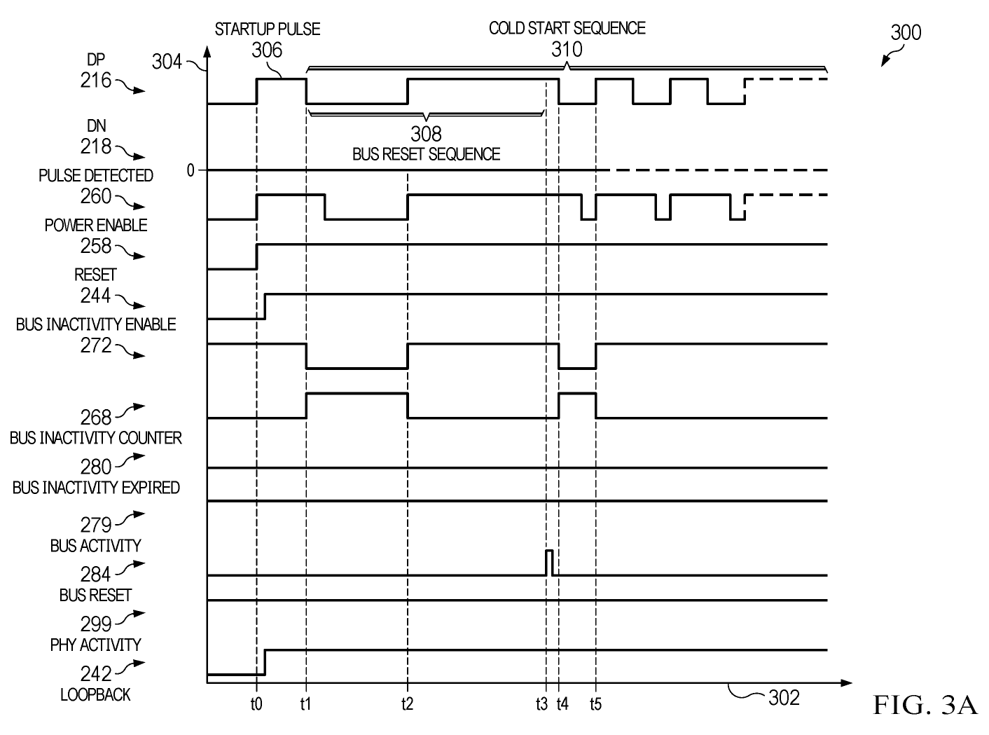

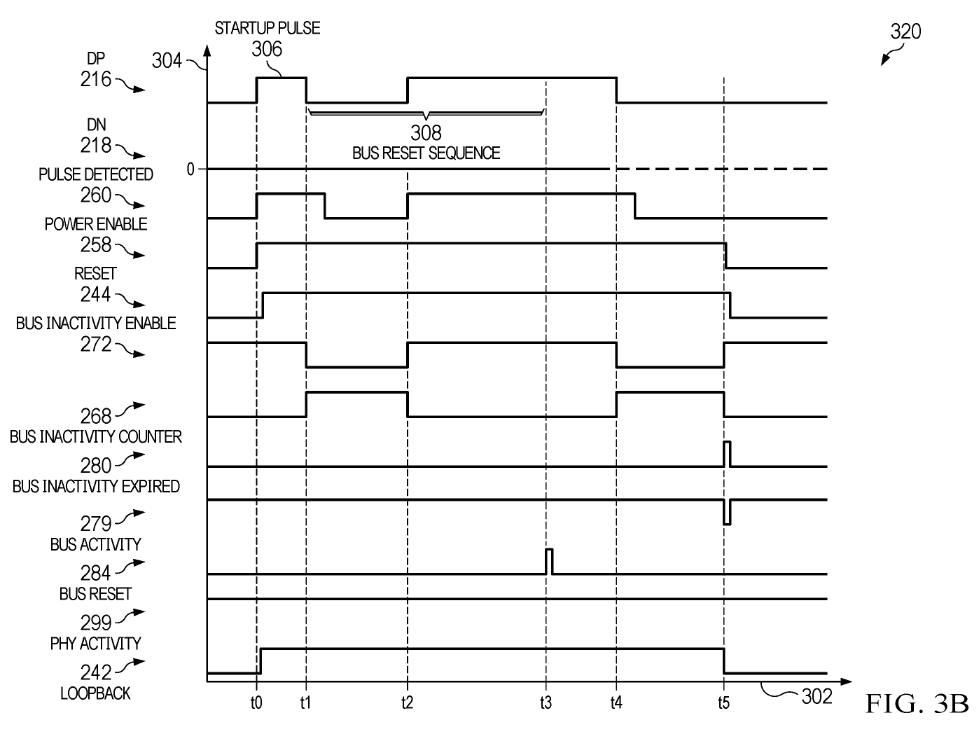

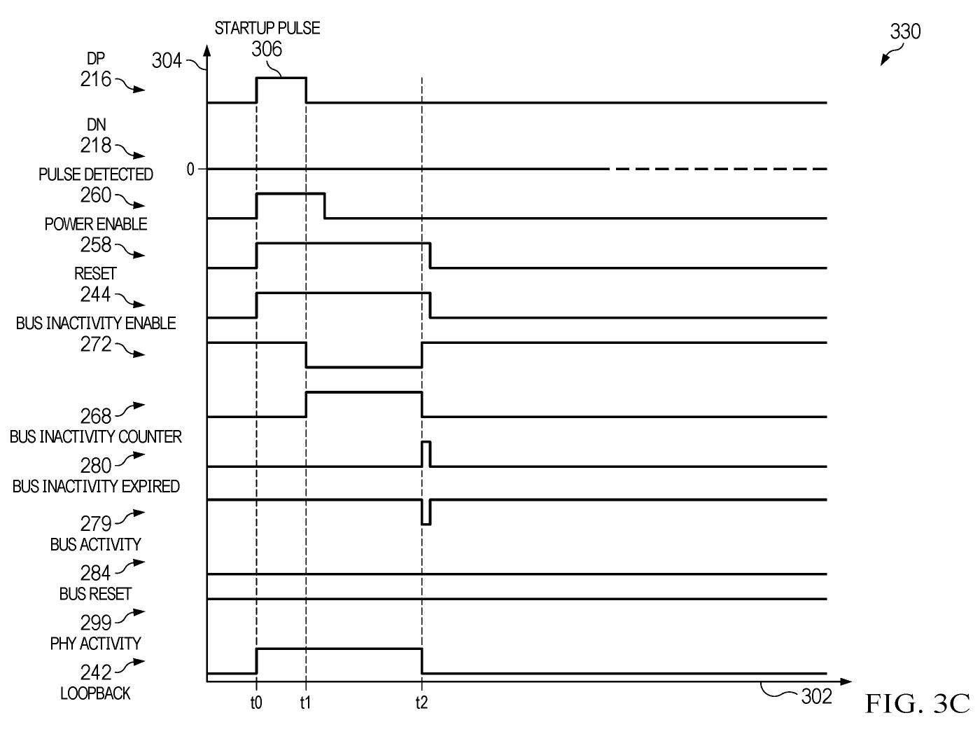

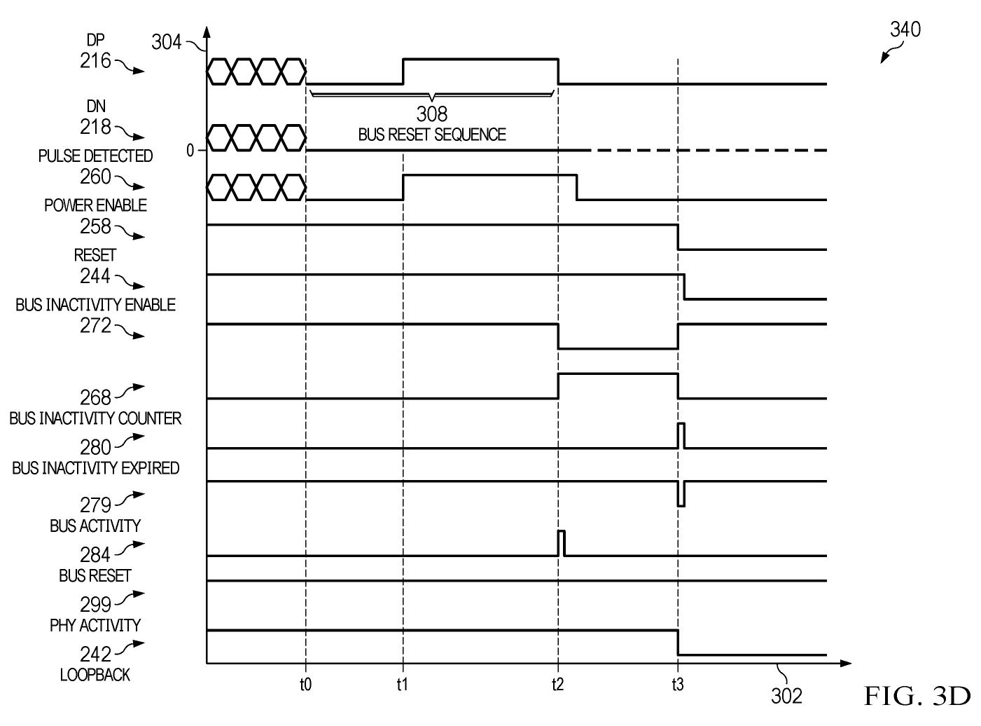

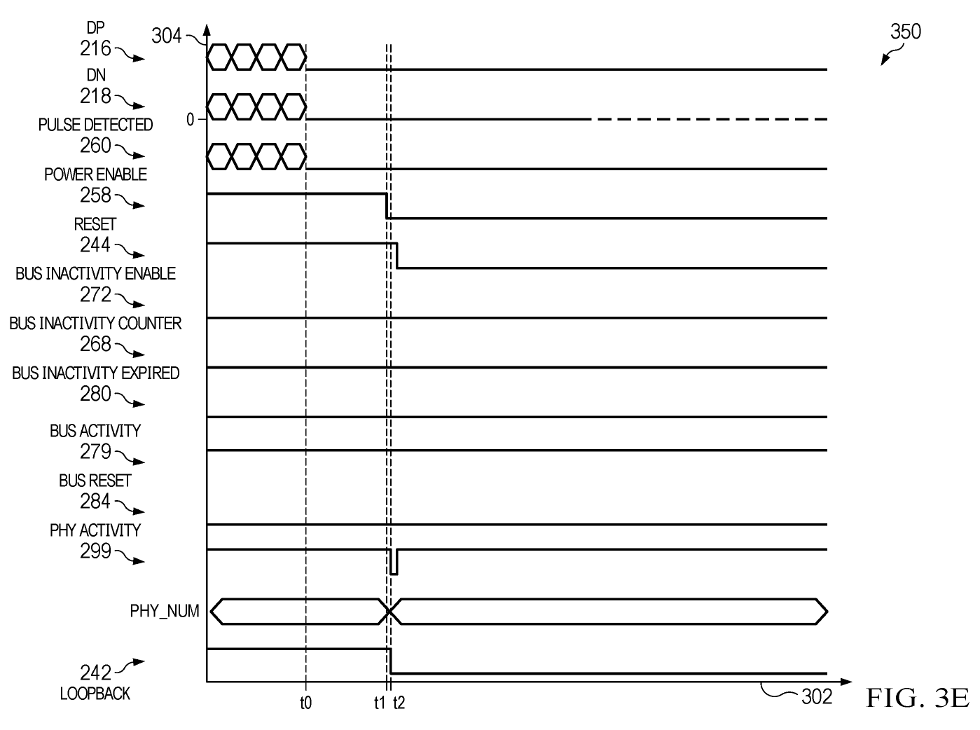

Accordingly, the loopback function of reset loopback circuit 226 enables the control circuitry of peripheral 204 (e.g., interface control circuit 228 and reset circuit 230) to power on for a period of time (e.g., temporary) to determine if there is activity on signal bus 219 and monitor signal bus 219 for a Cold Start sequence (including the Bus Reset sequence). If no further signals are received on signal bus 219 or the Cold Start sequence is not completed, the control circuitry (e.g., interface control circuit 228 and reset circuit 230) may power down. While interface control circuit 228 and reset circuit 230 power up to monitor signal bus 219, peripheral 204 may not transition from the Cold_Standby state until the Cold Start sequence is received. For example, peripheral 204 remains in the Cold_Standby state while interface control circuit 228 and reset circuit 230 are powered on until the Cold Start sequence is received and peripheral 204 transitions from the Cold_Standby state to a Link-Active state. Descriptions of this are explained in further detail below with respect to FIGS. 3A-3E.

Bus reset detection circuit 240 is configurable to hold PHY inactivity detection circuit 236 and bus inactivity detection circuit 238 in reset in response to detecting the Bus Reset sequence on signal bus 219. For example, while peripheral 204 is powered on (e.g., in a Link-Active or Link-Inactive state), bus reset detection circuit 240 monitors signal bus 219 for the Bus Reset sequence and activates a bus reset signal 284 in response to detecting the Bus Reset sequence on signal bus 219. For example, bus reset signal 284 may be active high so that bus reset detection circuit 240 asserts bus reset signal 284 high in response to detecting the Bus Reset sequence on signal bus 219. In other examples, bus reset detection circuit 240 asserts bus reset signal 284 low in response to not detecting the Bus Reset sequence on signal bus 219. In various examples, the Bus Reset sequence may be sent by the manager (e.g., manager 102) as part of a Cold Start sequence or to cause peripheral 204 to transition to one of the Link-Inactive states. Bus reset detection circuit 240 may activate bus reset signal 284 for a short period causing PHY inactivity detection circuit 236 and bus inactivity detection circuit 238 to reset (as described in further detail below).

Accordingly, the systems and methods described herein may enable a peripheral (e.g., peripheral 204) that is in a very low power state (e.g., the Cold_Standby state) to monitor a signal bus (e.g., signal bus 219) for a pulse signal and power on at least portions of the peripheral to monitor the signal bus for further signaling. For example, a reset circuit (e.g., reset circuit 230) may hold an interface control circuit (e.g., interface control circuit 228) in reset while in the Cold-Standby state. The reset circuit may detect a signal, or pulse, on the signal bus and power on the reset circuit and the interface control circuit to monitor for additional signaling without powering on all circuitry of the peripheral. In various examples, the interface control circuit may provide a loopback signal to the reset circuit to keep the interface control circuit out of reset for a predefined duration (e.g., the third duration) to monitor the signal bus for activity. If no bus activity is detected, the interface control circuit may deactivate the loopback signal, causing the reset circuit to reactivate the reset signal and power down the interface control circuit. If additional bus activity is detected, the interface control circuit may remain powered on to monitor the additional activity for control sequences from the manager (e.g., manager 102). The combination of signals and circuits described herein enable the peripheral to enter and exit a very low power state without the use of additional hardware pins or signals external to the signal bus.

Referring to FIGS. 3A-3E, timing diagrams of various signals of a peripheral (e.g., peripheral 204) as part of a system implementing the methods described herein are shown, according to various aspects of the present disclosure. In various examples, the system may be system 100 or system 200 and the peripheral may be peripherals 104 or peripheral 204, described above in FIGS. 1 and 2, respectively. As described above, the peripheral (e.g., peripheral 204) may implement the SWI3S™ protocol. As part of the power-up sequence, a manager (e.g., manager 102) may output a startup pulse 306 on signal bus 219 (e.g., on DP 216) followed by a Cold Start sequence 310 to initialize peripheral 204. As described herein, Cold Start sequence 310 may include a Bus Reset sequence 308. In various examples, and in accordance with the SWI3S™ protocol specification, Cold Start sequence 310 may be output on DP 216 while DN 218 may remain low during the initial power-up sequence of the system (e.g., system 200).

FIG. 3A shows a timing diagram 300 a normal power-up sequence. FIG. 3B shows a timing diagram 320 of a bus reset sequence of an incomplete Cold Start sequence. FIG. 3C shows a timing diagram 330 of an unintentional startup pulse. FIG. 3D shows a timing diagram 340 of a device power down from a bus reset signal (e.g., based on output from bus inactivity detection circuit 238). FIG. 3E shows a timing diagram 350 of a device power down from a Link-Active state because of PHY inactivity (e.g., based on output from PHY inactivity detection circuit 236) on the signal bus. Timing diagrams 300, 320, 330, 340, and 350 are used for illustrative and description purposes without implied limitation. As such, it is understood that timing diagrams 300, 320, 330, 340, and 350 may not fully illustrate the subject electrical signals as they occur in an actual device. Instead, timing diagrams 300, 320, 330, 340, and 350 illustrate the relative timing of the different events occurring during operation of the peripheral (e.g., peripheral 204).

Each timing diagram 300, 320, 330, 340, 350 includes a time axis 302 and a voltage axis 304. Timing diagrams 300, 320, 330, 340, 350 each show the behavior of (from top to bottom) DP 216, DN 218, pulse detected signal 260, power enable signal 258, reset signal 244, bus inactivity enable signal 272, bus inactivity counter signal 268, bus inactivity expired signal 280, bus activity signal 279, bus reset signal 284, PHY activity signal 299, and loopback signal 242. Each signal will be described below as being active or inactive and/or as being “low” (0) or “high” (1) where low and high are logic values within the circuit. For example, DP 216 and DN 218 are not described as being active or inactive, but as being low or high. As another example, some signals (e.g., reset signal 244) may be active low while other signals (e.g., loopback signal 242) may be active high. In various examples, “low” may correspond to a voltage of 0 V or a voltage less than 1.2 V (in a 3 V circuit) and “high” may correspond to a voltage greater than 1.7 V (in a 3 V circuit). Other voltages or values are possible to identify logic values of “low” and “high”. Time references (e.g., t1, t2, etc.) are used in the descriptions below. Changes in the signals may be described as occurring at a given time reference. In some examples, one or more signal changes may be shown as occurring after the time reference due to timer delays (e.g., timer 270, pulse detection circuit 250, etc.) and/or signal propagation delays in circuitry of the peripheral or timing.

Referring to FIG. 3A, timing diagram 300 of a normal power-up sequence (e.g., a first power up) of a peripheral as part of a system implementing the methods described herein is shown, according to various aspects of the present disclosure.

For purposes of illustration, in FIG. 3A, before the startup pulse 306, DP 216 is low, DN 218 is low, pulse detected signal 260 is low (e.g., inactive), power enable signal 258 is low (e.g., inactive), reset signal 244 is low (e.g., active), bus inactivity enable signal 272 is high (e.g., inactive), bus inactivity counter signal 268 is low (e.g., inactive), bus inactivity expired signal 280 is low (e.g., inactive), bus activity signal 279 is high (e.g., active), bus reset signal 284 is low (e.g., inactive), PHY activity signal 299 is high (e.g., active), and loopback signal 242 is low (e.g., inactive).

At time t0, peripheral 204 detects a rising edge of the startup pulse 306 (e.g., pulse signal, single pulse) as DP 216 transitions from low to high. Responsive to detecting the startup pulse 306, pulse detected signal 260 is asserted high (e.g., active). For example, pulse detection circuit 250 of reset circuit 230 asserts pulse detected signal 260 high in response to detecting startup pulse 306 on DP 216, as described above in FIG. 2B. Next, the power enable signal 258 of reset circuit 230 is asserted high (e.g., active) in response to pulse detected signal 260 being asserted high. As a result, as described above in FIG. 2B, POR circuit 246 powers on and, after a brief delay during which the power supplies stabilize, reset circuit 230 deactivates reset signal 244. For example, as shown in FIG. 3A, reset signal 244 is asserted high (e.g., inactive). Reset signal 244 being asserted high brings interface control circuit 228 out of reset and interface control circuit 228 asserts loopback signal 242 high (e.g., active) in response to reset signal 244, bus activity signal 279, and PHY activity signal 299 being high.

At time t1, peripheral 204 detects a falling edge of the startup pulse 306 as DP 216 transitions from high to low (e.g., a first portion of Bus Reset sequence 308). For example, pulse detection circuit 250 detects the falling edge of startup pulse 306 and maintains pulse detected signal 260 high (e.g., active) for a period of time past time t1 and then asserts pulse detected signal 260 low (e.g., inactive) before time t2 (e.g., the second duration). Bus inactivity enable signal 272 is asserted low (e.g., active) in response to the change in signal on DP 216 (e.g., the falling edge of the startup pulse 306). Bus inactivity counter signal 268 is asserted high (e.g., active) by logic circuit 276, in response to bus inactivity enable signal 272 being asserted low.

At time t2, peripheral 204 detects a rising edge of Bus Reset sequence 308 (e.g., a second portion of Bus Reset sequence 308) as DP 216 transitions from low to high. Responsive to the detecting the change in DP 216 (e.g., the second portion of Bus Reset sequence 308), pulse detected signal 260 is asserted high (e.g., active) and bus inactivity enable signal 272 is asserted high (e.g., inactive). Bus inactivity counter signal 268 is asserted low (e.g., inactive) by logic circuit 276 in response to DP 216 and bus inactivity enable signal 272 being high.

At time t3, bus reset signal 284 is asserted high (e.g., active) briefly by bus reset detection circuit 240 in response to Bus Reset sequence 308 being completed (e.g., both the first and second portions detected). Asserting bus reset signal 284 high causes logic circuit 296 to assert reset signal 283 (see FIG. 2C) low (e.g., active) which holds PHY inactivity detection circuit 236 and bus inactivity detection circuit 238 in reset while reset signal 283 is asserted low. As described in FIG. 2C, the inputs to logic circuit 296 are the reset signal 244 from reset circuit 230 and bus reset signal 284, inverted, from bus reset detection circuit 240 and logic circuit 296 generates reset signal 283 corresponding to a logical AND of reset signal 244 and inverted bus reset signal 284. Resetting PHY inactivity detection circuit 236 and bus inactivity detection circuit 238 ensures that both circuits are in a known state and ready to receive the remainder of Cold Start sequence 310. Resetting PHY inactivity detection circuit 236 and bus inactivity detection circuit 238 may not affect reset signal 244 because pulse detected signal 260 remains high (e.g., active), keeping reset signal 244 high (e.g., inactive).

At time t4, DP 216 transitions to low, bus reset detection circuit 240 has asserted bus reset signal 284 low (e.g., inactive), and both PHY inactivity detection circuit 236 and bus inactivity detection circuit 238 are out of reset in time for peripheral 204 to detect the next transition of DP 216 from high to low (e.g., continuing with the Cold Start sequence 310). Pulse detected signal 260 remains high (e.g., active) for a period time past time t4 and then is asserted low (e.g., inactive) before time t5 in response to the change in DP 216. Bus inactivity enable signal 272 is asserted low (e.g., active) in response to the falling edge of DP 216 and bus inactivity counter signal 268 is asserted high (e.g., active) in response to the change in bus inactivity enable signal 272.

At time t5, DP 216 continues the Cold Start sequence 310 as it transitions from low to high. Pulse detected signal 260 is asserted high (e.g., active) and bus inactivity enable signal 272 is asserted high (e.g., inactive) in response to the transition of DP 216. Bus inactivity counter signal 268 transitions from high to low (e.g., inactive) in response to the transition of bus inactivity enable signal 272 from low to high.

After time t5, Cold Start sequence 310 continues, initializing peripheral 204 for operation. For example, Cold Start sequence 310 causes peripheral 204 to transition from the Cold_Standby state to a Link-Active state. As described herein, the addition of the startup pulse 306 may not affect the Cold Start sequence 310. For example, the Bus Reset sequence 308 is not affected as part of Cold Start sequence 310. Instead, the startup pulse 306 provides a signal to peripheral 204 to power on reset circuit 230 and interface control circuit 228 to monitor signal bus 219 for the Cold Start sequence 310 (including Bus Reset sequence 308).

Referring to FIG. 3B, timing diagram 320 of an incomplete (or partial) Cold Start sequence on a signal bus during power up of a peripheral as part of a system implementing the methods described herein is shown, according to various aspects of the present disclosure. As described below, in some examples, the manager (e.g., manager 102) may output the Bus Reset sequence 308 but fail to output the remainder of the Cold Start sequence for various reasons including power disruption, signaling errors, data corruption, etc.

Times t0, t1, t2, and t3 of timing diagram 320 are the same as times t0, t1, t2, and t3 of timing diagram 300 described above in FIG. 3A and are not repeated below. After time t3, the Cold Start sequence is not completed and the peripheral responds as described below.

At time t4, the incomplete Cold Start sequence (e.g., not completed) transmitted on DP 216 results in peripheral 204 staying in the Cold_Standby state and reset loopback circuit 226 powering down. In contrast to timing diagram 300 of FIG. 3A, DP 216 remains high for an extended duration after the Bus Reset sequence 308 is detected. At time t4 of timing diagram 320 DP 216 transitions from high to low. Pulse detected signal 260 remains high (e.g., active) for a period time past time t4 and then is asserted low (e.g., inactive) before time t5. Bus inactivity enable signal 272 is asserted low (e.g., active), in response to the falling edge of DP 216, and bus inactivity counter signal 268 is asserted high (e.g., active) in response to the change in bus inactivity enable signal 272.

At time t5, bus inactivity expired signal 280 is asserted high (e.g., active) in response to the timer of timer circuit 270 expiring after detecting no activity on signal bus 219 for a predetermined time (e.g., the second duration about 250 µs to about 300 µs). Bus activity signal 279 is asserted low (e.g., inactive) in response to bus inactivity expired signal 280 being asserted high, causing loopback signal 242 to be asserted low (e.g., inactive) by logic circuit 295. Power enable signal 258 is asserted low (e.g., inactive) by logic circuit 254 in response to loopback signal 242 being asserted low, causing POR circuit 246 to disable power and logic circuit 256 to assert reset signal 244 low (e.g., active), holding interface control circuit 228 in reset.

Accordingly, timing diagram 320 shows an example in which peripheral 204 powers on in response to the startup pulse 306 and monitors signal bus 219 for additional activity. However, because the Cold Start sequence is not completed, peripheral 204 does not transition from the Cold_Standby state to a Link-Active state and instead powers down (e.g., enter very low power state) to wait for another startup pulse 306.

Referring to FIG. 3C, timing diagram 330 of an unintentional startup pulse on a signal bus is shown, according to various aspects of the present disclosure. As described below, in some examples, the manager (e.g., manager 102) may output the startup pulse 306 unintentionally so that it is not followed by either the Bus Reset sequence or the remainder of Cold Start sequence.

Times t0 and t1 of timing diagram 330 are the same as times t0 and t1 of timing diagram 300 described above in FIG. 3A and are not repeated below. However, in timing diagram 330 no additional data is transmitted on DP 216 after the startup pulse 306. In other words, timing diagram 330 does not include the Cold Start sequence (including the Bus Reset sequence) after startup pulse 306.

At time t2, bus inactivity expired signal 280 is asserted high (e.g., active) in response to the timer of timer circuit 270 expiring after detecting no activity on signal bus 219 for a predetermined time (e.g., the second duration about 250 µs to about 300 µs). Bus activity signal 279 is asserted low (e.g., inactive) in response to bus inactivity expired signal 280 being asserted high, causing loopback signal 242 to be asserted low (e.g., inactive) by logic circuit 295. A short time later, power enable signal 258 is asserted low (e.g., inactive) by logic circuit 254 in response to loopback signal 242 being asserted low, causing POR circuit 246 to disable power and logic circuit 256 to assert reset signal 244 low (e.g., active), holding interface control circuit 228 in reset.

Accordingly, timing diagram 330 shows an example in which peripheral 204 powers on in response to the startup pulse 306 and monitors signal bus 219 for additional activity. However, because no additional signals are received, peripheral 204 powers down (e.g., enter very low power state) to wait for another startup pulse 306.

Referring to FIG. 3D, timing diagram 340 is a power down sequence of a peripheral (e.g., peripheral 204) in response to the Bus Reset sequence 308 (e.g., in a Link-Inactive state) on a signal bus (e.g., signal bus 219). Timing diagram 340 demonstrates that the addition of the startup pulse 306 and associated circuitry (e.g., bus inactivity detection circuit 238 and pulse detection circuit 250) may not affect the functionality of peripheral 204 in other scenarios (e.g., power down from bus reset). The inclusion of this power down sequence is provided for completeness, as it illustrates the operation of peripheral 204 under different conditions.

At time t0, the manager sends the Bus Reset sequence 308 on DP 216. The Bus Reset sequence 308 includes a first portion that is low for a first time period and a second portion that is high for a first time period, as described in the SWI3S™ specification. Accordingly, DP 216 is low and pulse detected signal 260 asserts low (e.g., inactive) in response to DP 216 being low.

At time t1, DP 216 transitions from low to high, transitioning from the first portion to the second portion of the Bus Reset sequence 308. The peripheral 204 tracks the time that DP 216 was low and the transition to high as being part of the Bus Reset sequence 308. The pulse detected signal 260 transitions to high (e.g., active) in response to DP 216 transitioning to high.

At time t2, DP 216 transitions to low and bus reset signal 284 is asserted high (e.g., active) briefly by bus reset detection circuit 240 in response to Bus Reset sequence 308 being completed (e.g., both the first and second portions detected). Asserting bus reset signal 284 high causes logic circuit 296 to assert reset signal 283 (see FIG. 2C) low, holding both PHY inactivity detection circuit 236 and bus inactivity detection circuit 238 in reset until bus reset signal 284 is asserted low (e.g., inactive). As described in FIG. 2C, the inputs to logic circuit 296 are the reset signal 244 (from reset circuit 230) and bus reset signal 284, inverted (from bus reset detection circuit 240). Logic circuit 296 generates reset signal 283 corresponding to a logical AND of reset signal 244 and inverted bus reset signal 284. At time t2, both PHY inactivity detection circuit 236 and bus inactivity detection circuit 238 return to monitoring the signal bus 219 for activity.

At time t3, bus inactivity expired signal 280 is asserted high (e.g., active) in response to the timer of timer circuit 270 expiring after detecting no activity on signal bus 219 for a predetermined time (e.g., the second duration about 250 µs to about 300 µs). Bus activity signal 279 is asserted low (e.g., inactive) in response to bus inactivity expired signal 280 being asserted high, causing loopback signal 242 to be asserted low by logic circuit 295. Power enable signal 258 is asserted low (e.g., inactive) by logic circuit 254 in response to loopback signal 242 being asserted low, causing POR circuit 246 to disable power and logic circuit 256 to assert reset signal 244 low (e.g., active) after a brief delay, holding interface control circuit 228 in reset. The state of the peripheral 204 may be determined by data received before time t0. In some examples, the peripheral 204 may be in the Cold_Standby state after time t3. In other examples, the peripheral 204 may be in the Sleeping state after time t3.

Accordingly, timing diagram 340 shows an example in which peripheral 204 is operating and powers down in response the Bus Reset sequence 308. The additional circuitry and timing implemented to manage the very low power of the Cold_Standby state do not affect the power down operation of peripheral 204.

Referring to FIG. 3E, timing diagram 350 is a power down sequence of a peripheral (e.g., peripheral 204) in response PHY inactivity while in a Link-Active state. Timing diagram 350 demonstrates that the addition of the startup pulse 306 and associated circuitry (e.g., bus inactivity detection circuit 238 and pulse detection circuit 250) may not affect the functionality of peripheral 204 in other scenarios (e.g., power down from PHY inactivity). The inclusion of this power down sequence is provided for completeness, as it illustrates the operation of peripheral 204 under different conditions.

Timing diagram 350 does not include the startup pulse 306 and is described herein for completeness and to demonstrate that the systems and methods disclosed herein do not negatively impact the performance of peripheral 204. While no startup pulse is transmitted on DP 216, FIG. 3E shows that the circuitry for handling the startup pulse does not affect the functionality of peripheral 204 with respect to other conditions/scenarios.

Before time t0, system 100 including manager 102 and peripherals 104 are sending and receiving signals on signal bus 119. For example, peripheral 204 is sending and receiving messages on signal bus 219 including on DP 216 and DN 218. As shown, pulse detected signal 260 responds to the changes in DP 216 during operation of peripheral 204.

At time t0, signal bus 219 activity, including PHY activity stops. DP 216 and DN 218 remain low and pulse detected signal 260 remains low in response to DP 216 being low.

At time t1, power enable signal 258 is asserted low (e.g., inactive) in response to pulse detected signal 260 being low for the second duration (e.g., about 20 µs to about 60 µs).

At time t2, PHY activity signal 299 is asserted low (e.g., inactive) in response to no activity being present on signal bus 219. Loopback signal 242 is asserted low (e.g., inactive) in response to PHY activity signal 299 being asserted low. After a short delay, reset signal 244 is asserted low (e.g., active) in response to the loopback signal 242 being asserted low holding interface control circuit 228 in reset, thereby powering down peripheral 204.

Accordingly, timing diagram 330 shows an example in which peripheral 204 powers down in response to not detecting PHY activity on signal bus 219. The additional circuitry and timing implemented to manage the very low power of the Cold_Standby state do not affect the power down operation of peripheral 204.

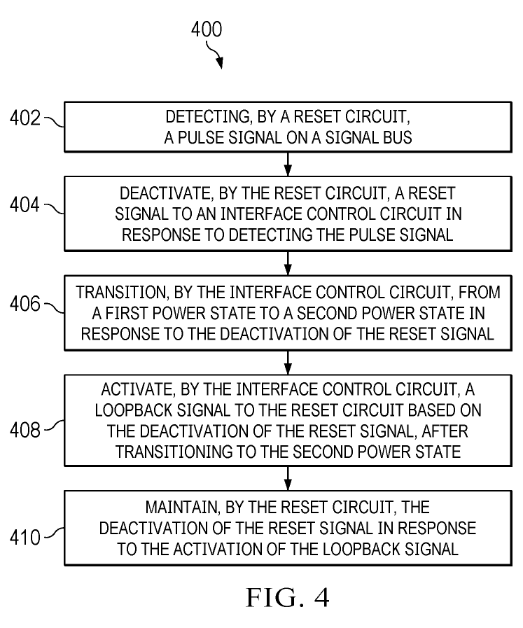

Referring to FIG. 4, a method 400 for exiting the Cold_Standby state based on bus signal is illustrated, according to various aspects of the present disclosure. In some examples, method 400 may be performed by a peripheral (e.g., first peripheral 104a, second peripheral 104b, and/or third peripheral 104c) of system 100, described above in FIG. 1. In some examples, method 400 may be performed by peripheral 204, described above in FIGS. 2A-2C. Additional processes can be provided before, during, and after method 400.

At step 402, a reset circuit (e.g., reset circuit 230) detects a pulse signal (e.g., startup pulse 306) on a signal bus (e.g., signal bus 119 or signal bus 219). At step 404, the reset circuit deactivates a reset signal (e.g., reset signal 244) to an interface control circuit (e.g., interface control circuit 228) in response to detecting the pulse signal. At step 406, the interface control circuit transitions from a first power state to a second power state in response to the deactivation of the reset signal. At step 408, the interface control circuit activates a loopback signal (e.g., loopback signal 242) to the reset circuit based on the deactivation of the reset signal, after transitioning to the second power state. At step 410, the reset circuit receives maintains the deactivation of the reset signal in response to the activation of the loopback signal.

In some examples of method 400, the interface control circuit monitors the signal bus for signaling activity while the reset signal is deactivated by the reset circuit based on the loopback signal. In some examples of method 400, the interface control circuit is further configurable to monitor the signal bus for a bus reset sequence. In some examples of method 400, the interface control circuit is further configurable to determine that the signal bus is inactive after detecting the bus reset sequence. In some examples of method 400, the interface control circuit is further configurable to determine that the signal bus is inactive in response to the absence of signaling transitions on the signal bus for at least a predetermined duration. In various examples, the predetermined duration may be about 200 µs to about 300 µs.

Accordingly, disclosed herein are systems and methods for enabling a peripheral implementing the SWI3S™ protocol to draw little to no power while in the Cold_Standby state and respond to signals on the signal bus. In various examples, a reset loopback circuit including a reset circuit and an interface control circuit may be implemented. In some examples, the reset circuit includes a pulse detection circuit that is configurable to enable a power-on reset (POR) circuit in response to detecting a signal on the signal bus. The POR circuit may deactivate a reset signal so that the interface control circuit can monitor the signal bus for additional signaling. In various examples, the interface control circuit may activate a loopback signal to the POR circuit to keep the POR circuit enabled and the reset signal deactivated while the interface control circuit monitors the signal bus. If the interface control circuit does not detect signaling on the signal bus for a predetermined duration, the loopback signal may be deactivated and the POR circuit may activate the reset circuit to hold the interface control circuit in reset so that the peripheral remains in the Cold_Standby state. If additional signals are detected on the signal bus, the peripheral may transition from the Cold_Standby state and resume operation.

Finally, it should be understood that any of the above-described concepts can be used alone or in combination with any or all of the other above-described concepts. Although various examples have been disclosed and described, it is understood, recognized, and/or contemplated that certain modifications would come within the scope of this disclosure. Accordingly, the description is not intended to be exhaustive or to limit the principles described or illustrated herein to any precise form. Many modifications and variations are possible in light of the above teaching.

What is claimed is:

1. A method, comprising:
detecting, by a reset circuit, a pulse signal on a signal bus;
deactivating, by the reset circuit, a reset signal to an interface control circuit in response to detecting the pulse signal;
transitioning, by the interface control circuit, from a first power state to a second power state in response to the deactivation of the reset signal;
activating, by the interface control circuit, a loopback signal to the reset circuit based on the deactivation of the reset signal, after transitioning to the second power state; and
maintaining, by the reset circuit, the deactivation of the reset signal in response to the activation of the loopback signal.

2. The method of claim 1, wherein:
the first power state is a power down state;
the second power state is a power on state; and
the first power state and the second power occur in a Cold_Standby state.

3. The method of claim 1, further comprising:
enabling, by the interface control circuit, a first timer circuit in response to transitioning to the second power state, wherein the first timer circuit activates a bus activity signal for a first duration;
deactivating, by the first timer circuit, the bus activity signal after the first duration;
deactivating, by the interface control circuit, the loopback signal in response to deactivating the bus activity signal;
activating, by the reset circuit, the reset signal in response to deactivating the loopback signal; and
transitioning, by the interface control circuit, to the first power state in response to the reset signal being activated by the reset circuit.

4. The method of claim 3, further comprising:
enabling, by the interface control circuit, a second timer circuit in response to transitioning to the second power state, wherein the second timer circuit is configurable to activate a physical interface activity signal for a second duration that is greater than the first duration, the physical interface activity signal indicating activity on the signal bus; and
activating, by the interface control circuit, the loopback signal based on the reset signal, the bus activity signal, and the physical interface activity signal.

5. The method of claim 4, wherein the pulse signal has a third duration to begin a reset process, the method further comprising:
enabling, by the reset circuit, a third timer circuit configurable to activate a pulse detection signal for a fourth duration in response to detecting the pulse signal, the fourth duration being greater than the third duration to activate the pulse detection signal for longer than the pulse signal.

6. The method of claim 5, wherein:
the first duration is about 200 µs to about 300 µs;
the second duration is about 400 µs to about 600 µs;
the third duration is about 1 µs to about 5 µs; and
the fourth duration is about 20 µs to about 60 µs.

7. The method of claim 1, further comprising:
generating, by the reset circuit, a power enable signal in response to detecting the pulse signal on the signal bus;
selectively coupling, by the reset circuit, a power-on reset (POR) circuit to a power source in response to the power enable signal; and
deactivating, by the reset circuit, the reset signal in response to the power source of the POR circuit reaching a predetermined power level.

8. A device, comprising:
a reset circuit coupled to a signal bus, the reset circuit configurable to:
provide a pulse detected signal in response to a pulse signal on the signal bus;
provide an enable power signal based on the pulse detected signal and a loopback signal; and
provide a reset signal in response to the enable power signal; and
an interface control circuit coupled to the reset circuit, the interface control circuit configurable to:
receive the reset signal from the reset circuit; and
provide the loopback signal to the reset circuit based on the reset signal.

9. The device of claim 8, wherein the reset circuit includes:
a power-on reset circuit coupled to a power supply and configurable to:
receive the enable power signal; and
deactivate the reset signal in response to the enable power signal and the power supply reaching a predetermined threshold; and
a pulse detection circuit coupled to the signal bus and the power-on reset circuit, the pulse detection circuit configurable to:
detect the pulse signal on the signal bus, the pulse signal having a first duration; and
provide the pulse detected signal for a second duration that is greater than the first duration in response to detecting the pulse signal.

10. The device of claim 9, wherein the reset circuit further includes:
a logic circuit configurable to:
receive the pulse detected signal and the loopback signal; and
provide the enable power signal in response to either the pulse detected signal or the loopback signal.

11. The device of claim 8, wherein the interface control circuit includes:
a bus inactivity detection circuit coupled to the signal bus and configurable to:
detect a first signal on the signal bus;
enable a timer for a third duration in response to detecting the first signal; and
provide a bus activity signal for the third duration, wherein the loopback signal is further based on the bus activity signal.

12. The device of claim 11, wherein the bus inactivity detection circuit is further configurable to reenable the timer for the third duration in response to detecting a second signal on the signal bus.

13. The device of claim 11, wherein:
the interface control circuit includes a physical interface activity detection circuit coupled to the signal bus, the physical interface activity detection circuit configurable to:
detect the first signal on the signal bus; and
provide a physical interface activity signal in response to detecting the pulse signal, wherein the loopback signal is further based on the physical interface activity signal.

14. The device of claim 8, wherein the device is configurable to operate with the SoundWire® I3S protocol.

15. A system, comprising:
a signal bus;
a manager device coupled to the signal bus, the manager device configurable to transmit a signal on the signal bus; and
a peripheral device coupled to the signal bus, the peripheral device configurable to:
detect the signal on the signal bus while the peripheral device is in a first state;
power on the peripheral device in response to the signal, while in the first state; and
monitor the signal bus for a cold start sequence to transition the peripheral device into a second state.

16. The system of claim 15, wherein the signal is a single pulse.

17. The system of claim 15, wherein:
the first state is a Cold_Standby state;
the second state is a Link-Active state; and
the cold start sequence includes a bus reset sequence.

18. The system of claim 15, wherein:
the manager device is further configurable to transmit signaling on the signal bus after the signal, the signaling including the bus reset sequence; and
the peripheral device is further configurable to detect the signaling on the signal bus and transition to the second state in response to detecting the cold start sequence.

19. The system of claim 18, wherein the peripheral device is further configurable to:
determine that the signal bus is inactive in response to the absence of signaling transitions on the signal bus for at least a predetermined duration; and
maintain the first state in response to the signal bus being inactive.

20. The system of claim 15, wherein signal bus includes:
a data negative signal line; and
a data positive signal line.
